(19) United States
(12) Patent Application Publication
(10) Pub. No.: US 2025/0203932 A1
(43) Pub. Date: Jun. 19, 2025

(54) SEMICONDUCTOR DEVICE AND FABRICATING METHOD THEREOF

(71) Applicant: UNITED MICROELECTRONICS CORP., Hsin-Chu City (TW)

(72) Inventors: YUSHAN CHEN, Singapore (SG); Lu Zou, Singapore (SG); Yikun Chen, Singapore (SG)

(73) Assignee: UNITED MICROELECTRONICS CORP., Hsin-Chu City (TW)

(21) Appl. No.: 18/415,629

(22) Filed: Jan. 17, 2024

(30) Foreign Application Priority Data
Dec. 13, 2023 (TW) 112148427

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/013; H10D 84/0149; H10D 84/038; H10D 84/83

(57) ABSTRACT

A semiconductor device and fabricating method thereof includes a plurality of nanowire structures, a first source/drain structure and a second source/drain structure, a gate structure, and a gate dielectric layer. The nanowire structures are extended in a vertical direction. The first source/drain structure and the second source/drain structure are stacked in the vertical direction. The gate structure is disposed between the first source/drain structure and the second source/drain structure in the vertical direction, wherein the first source/drain structure, the second source/drain structure, and the gate structure respectively wraps a portion of each of the nanowire structures. The gate dielectric layer is disposed between the gate structure and each of the nanowire structures, and between the gate structure and the first source/drain structure.

### BACKGROUND OF THE INVENTION

### 1. Field of the Invention

The invention relates to a semiconductor device and a fabricating method thereof, and more particularly, to a semiconductor device having a nanowire structure and a fabricating method thereof.

### 2. Description of the Prior Art

Conventional planar metal-oxide-semiconductor (MOS) transistor has difficulty when scaling down to 65 nm and below. Therefore the non-planar transistor technology such as fin field effect transistor (FinFET) technology that allows smaller size and higher performance is developed to replace the planar MOS transistor. For example, dual-gate FinFET device, tri-gate FinFET device, and omega-FinFET device have been provided. Currently, a gate-all-around field effect transistor (GAAFET) device using a nanowire structure as a channel is further developed, for achieving the ongoing goals of high performance, increased miniaturization of integrated circuit components, and greater packaging density of integrated circuits.

### SUMMARY OF THE INVENTION

It is one of the primary objectives of the present invention to provide a semiconductor device and a fabricating method thereof, in which a nanowire structure is vertically disposed therein to form a gate-all-around field effect transistor subsequently. Accordingly, the semiconductor device of the present disclosure enables to effectively increase the channel width without increasing the occupied area of the transistor, and to improve the reliability and the integration of electronic transmission. In this way, the semiconductor device of the present disclosure may not only reduce the current leakage, but also gain better performance by improving the functions and reducing the power consumption through adjusting the channel thickness of the semiconductor device.

To achieve the purpose described above, the present invention provides a semiconductor device including a plurality of nanowire structures, a first source/drain structure and a second source/drain structure, a gate structure, and a gate dielectric layer. The nanowire structures are extended in a vertical direction. The first source/drain structure and the second source/drain structure are stacked in the vertical direction. The gate structure is disposed between the first source/drain structure and the second source/drain structure in the vertical direction, wherein the first source/drain structure, the second source/drain structure and the gate structure respectively wraps a portion of each of the nanowire structures. The gate dielectric layer is disposed between the gate structure and each of the nanowire structures, and between the gate structure and the first source/drain structure.

To achieve the purpose described above, the present invention provides a fabricating method of a semiconductor device including the following steps. A plurality of nanowire structures are formed to extend in a vertical direction. A source structure and a drain structure are formed to stack sequentially in the vertical direction. A gate structure is formed between the first source/drain structure and the second source/drain structure in the vertical direction, wherein the first source/drain structure, the gate structure, and the second source/drain structure respectively wraps a portion of each of the nanowire structures. A gate dielectric layer is formed between the gate structure and each of the nanowire structures, and between the gate structure and the first source/drain structure.

Overall speaking, the semiconductor device of the present disclosure includes two source/drain structures and a gate structure stacked in sequence in the vertical direction to respectively wrap a portion of a nanowire structure, to jointly form a gate-all-around field effect transistor having a vertical channel. With these arrangements, the semiconductor device of the present disclosure may effectively increase the channel width without increasing occupied area of the transistor, and improve the reliability and integration of electron transmission, thereby achieving better operation performance. Moreover, the semiconductor device is allowable to be further applied to a three-dimensional stacked structure, by further electrically connecting to other functional devices or components such as a memory device, a logic device, a central processing unit or an analog device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 are schematic diagrams of a semiconductor device according to a preferably embodiment of the present disclosure, wherein:

FIG. 1 is a schematic three-dimensional view of a semiconductor device according to the preferably embodiment of the present disclosure; and

FIG. 2 is a schematic cross-sectional view of a semiconductor device according to the preferably embodiment of the present disclosure.

FIG. 3 to FIG. 11 are schematic diagrams of a fabricating method of a semiconductor device according to a preferable embodiment of the present disclosure, in which:

FIG. 3 is a schematic cross-sectional view of a semiconductor device after forming nanowire structures;

FIG. 4 is a schematic cross-sectional view of a semiconductor device after trimming the nanowire structure;

FIG. 5 is a schematic cross-sectional view of a semiconductor device after forming a dielectric material layer;

FIG. 6 is a schematic cross-sectional view of a semiconductor device after forming a metal material layer;

FIG. 7 is a schematic cross-sectional view of a semiconductor device after forming a spacer;

FIG. 8 is a schematic cross-sectional view of a semiconductor device after forming a conductive material layer;

FIG. 9 is a schematic cross-sectional view of a semiconductor device after forming an interconnection layer;

FIG. 10 is a schematic cross-sectional view of a semiconductor device after thinning down the substrate; and

FIG. 11 is a schematic cross-sectional view of a semiconductor device after forming another interconnection layer.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

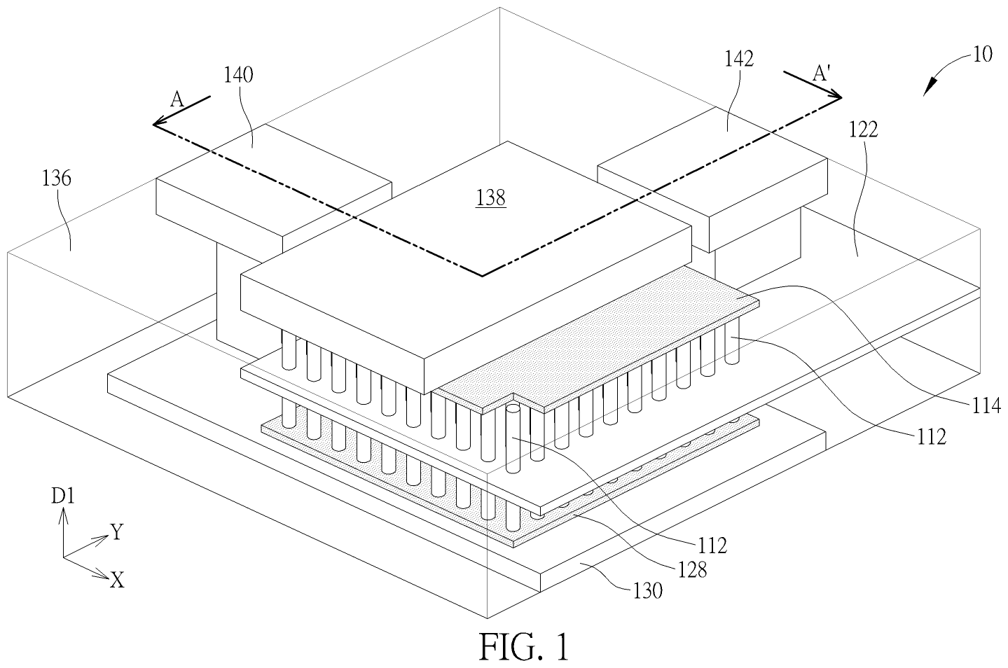

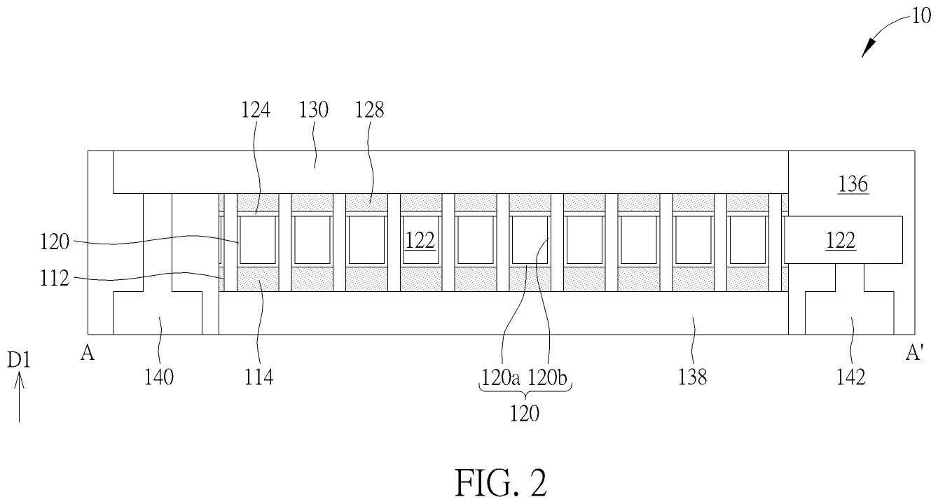

Please refer to FIG. 1 and FIG. 2, which are schematic diagrams of a semiconductor device 10 according to a preferably embodiment of the present disclosure, with a FIG. 1 illustrating three-dimensional view of the semiconductor device 10, and with FIG. 2 illustrating a cross-sectional view taken along a cross-line A-A′ in FIG. 1. The semiconductor device 10 includes a plurality of nanowire structures 112, a first source/drain structure 114 and a second source/drain structure 128, a gate structure 122, and a gate dielectric layer 120. The nanowire structures 122 for example extend in a vertical direction D1, with the nanowire structures 122 individually presenting in a cylindrical structure as shown in FIG. 1 to arrange in an array, but not limited thereto. In one embodiment, the nanowire structures 112 for example include a single crystal material such as silicon (Si), epitaxial silicon, silicon germanium (SiGe), or silicon carbide (Sic), but not limited thereto. The first source/drain structure 114, the gate structure 122, and the second source/drain structure 128 are stacked sequentially in the vertical direction D1, to respectively wrap a portion of each of the nanowire structures 112. Also, the gate dielectric layer 120 is disposed between the gate structure 122, the nanowire structures 112, and the first source/drain structure 114, to isolate the aforementioned elements from each other. With these arrangement, the gate structure 122 is disposed between the first source/drain structure 114 and the second source/drain structure 128, with each of the first source/drain structure 114, the gate structure 122, and the second source/drain structure 128 covering a portion of each of the nanowire structures 112, to together form a transistor having a vertical extended channel. Accordingly, the first source/drain structure 114 and the second source/drain structure 128 respectively serves as two source/drain of the transistors, and the nanowire structures covered by the gate structure 122 serves as the vertical channel of the transistor, such that, the gate structure 122 surrounding outside the vertical channel will therefore perform like a gate-all-around (GAA).

In one embodiment, the first source/drain structure 114, the gate structure 122 and the second source/drain structure 128 for example include a doped semiconductor material with a lower resistance or a metal material, for example including but not limited to silicon (Si), silicon germanium (SiGe), titanium (Ti), tantalum (Ta), aluminum (Al), copper (Cu), tungsten (W) or a combination thereof. The first source/drain structure 114 and the second source/drain structure 128 preferably include the same conductive material, and the gate structure 122 preferably includes a metal material, but is not limited thereto.

Precisely speaking, the gate dielectric layer 120 further includes a first portion 120a disposed between the gate structure 122 and the first source/drain structure 114 underneath, and a second portion 120b disposed between the gate structure 122 and each of the nanowire structures 122. In one embodiment, the first portion 120a and the second portion 120b of the gate dielectric layer 120 are both formed through the same deposition process, and both include the same dielectric material such as silicon oxide (SiO₂), silicon nitride (SiN), silicon oxynitride (SiON) or a suitable material with a low-dielectric constant, but not limited thereto. In another embodiment, the first portion 120a and the second portion 120b of the gate dielectric layer 120 may also be formed through a thermal oxidation process, so that, the first portion 120a and the second portion 120b may include different dielectric materials. Furthermore, the semiconductor device 10 may further includes a spacer 124 covering the gate structure 122, and disposed between the second source/drain structure 128 and the gate structure 122, to electrically isolate the second source/drain structure 128 and the gate structure 122 underneath. In one embodiment, the spacer 124 for example also includes a dielectric material such as silicon oxide, silicon nitride, silicon oxynitride, or a suitable material with a low-resistant constant, but not limited thereto. It is noted that, in order to clearly illustrate the vertical channel and the gate-all-around transistor of the present embodiment, some elements like the spacer 124 and the gate dielectric layer 120 are not illustrated in FIG. 1. However, people skilled in the art should be able to realize the locations of these elements in FIG. 1 through the schematic cross-sectional view of the semiconductor device 10 as shown in FIG. 2.

Further in view of FIG. 1 and FIG. 2, the semiconductor device 10 further includes a first interconnection layer 138 stacked below the transistor in the vertical direction D1, and a second interconnection layer 130 stacked above the transistor in the vertical direction D1. The first interconnection layer 138 and the second interconnection layer 130 are both disposed in an insulating layer 136, being surrounded by the insulating layer 136 and to directly in contact with the first source/drain structure 114 and the second source/drain structure 128, respectively. In one embodiment, the first interconnection layer 138 and the second interconnection layer 130 for example include a low-resistant metal material like titanium, tantalum, aluminum, copper, tungsten, or a combination thereof, to connect to the first source/drain structure 114 and the second source/drain structure 128. Accordingly, the first source/drain structure 114 and the second source/drain structure 128 of the transistor may further connect to other functional devices or elements, such as a memory device, a logic device, a central processing unit (CPU) or an analogue device, through the first interconnection layer 138 and the second interconnection layer 130.

For example, in the present embodiment, a package layer (not shown in FIG. 1 and FIG. 2) may be further disposed on the second interconnection layer 130, covering and sealing a side of the transistor (namely, the side where the second source/drain structure 128 is located). Then, the second source/drain structure 128 of the transistor and the gate structure 122 may be further connected to a side where the first source/drain structure 114 of the transistor is located, through conductive structures 140, 142 which are electrically connected to the second interconnection layer 130 and the gate structure 122, respectively. The conductive structures 140, 142 are both disposed within the insulating layer 136, and which are respectively disposed in a horizontal direction X of the first interconnection layer 138 and a direction Y being perpendicular to the horizontal direction X, with the conductive structures 140, 142 being both coplanar with a surface (such as the top surface as shown in FIG. 1 or the bottom surface as shown in FIG. 2) of the first interconnection layer 138, as shown in FIG. 1. In one embodiment, the conductive structure 140, 142 for example include a suitable plug and/or a conductive layer, which may include a low-resistant metal material like titanium, tantalum, aluminum, copper or tungsten, but not limited thereto. Accordingly, the first source/drain structure 114 and the second source/drain structure 128 of the transistor, and the gate structure 122 may be electrically connected to above-mentioned functional devices, through the first interconnection layer 138 and the conductive structures 140 and 142 arranged at the same side of the transistor (the side where the first source/drain structure 114 is located), but not limited thereto. In another embodiment, the first source/drain structure 114 and the second source/drain structure 128 of the transistor may also be connected to different sides of the transistor, and next connected to above-mentioned functional devices, respectively.

According to the semiconductor device 10 of the present disclosure, the first source/drain structure 114, the gate structure 122, and the second source/drain structure 128 are sequentially disposed in the vertical direction D1, to respectively wrap a portion of each of the nanowire structures 112, so that, the nanowire structures 112, the gate structure 122, the first source/drain structure 114, and the second source/drain structure 128 will together form the transistor with the vertical channel, thereby effectively increasing the channel width without increasing the occupied area of the transistor, so as to improve the reliability and integration of electronic transmission. In this way, the semiconductor device 10 of the present disclosure is allowable to not only reduce the current leakage, but also gain better performance by improving the functions and reducing the power consumption through adjusting the channel thickness of the semiconductor device 10.

In order to make people skilled in the art of the present disclosure easily understand the semiconductor device 10 of the present disclosure, a fabricating method of the semiconductor device 10 in the present disclosure will be further described below.

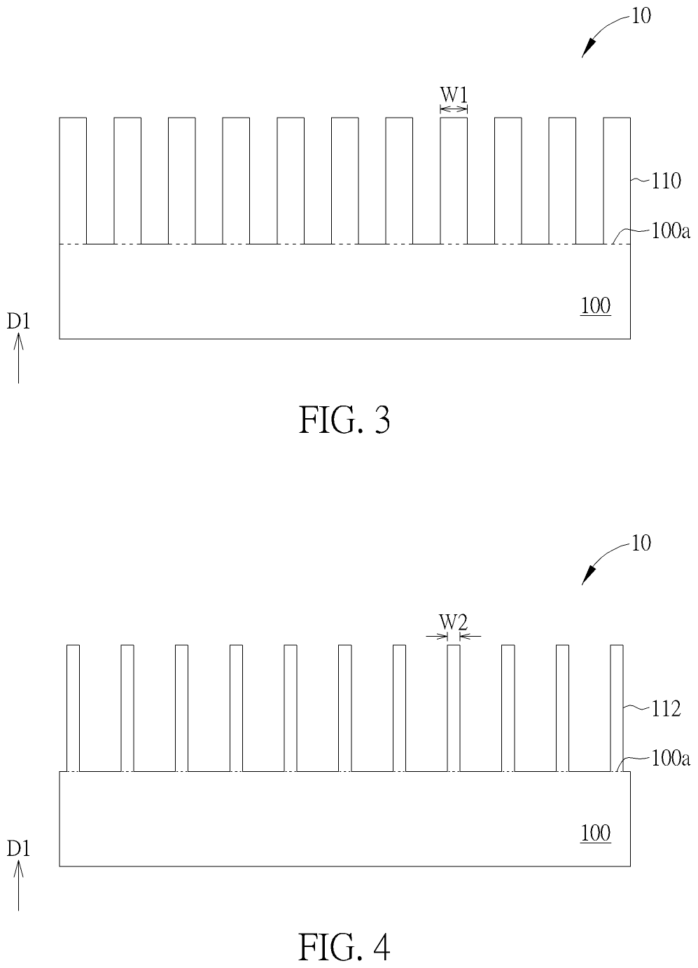

Please refer to FIG. 3 to FIG. 11, which are schematic diagrams of a fabricating method of a semiconductor device 10 according to a preferable embodiment of the present disclosure. Although only the cross-sectional views of the semiconductor device 10 during each step of the fabricating method are illustrated in the present embodiment, people skilled in the art may fully realize the corresponding top view of the semiconductor device 10 in each step, as reference to the top view of the semiconductor device 10 as shown in FIG. 1.

Firstly, as shown in FIG. 3, a plurality of nanowire structures 110 is formed on a top surface 100a of a substrate 100, in the vertical direction D1, with each of the nanowire structures 110 having a width W1 for example being about 1 nanometer (nm) to 1000 nanometers, but not limited thereto. People skilled in the art should fully understand that the nanowire structures 110 may optionally include different materials for providing corresponding stresses, thereby presenting in an N-type channel or a P-type channel due to practical process requirements. In one embodiment, the formation of the nanowires 110 includes but not limited to the following steps. Firstly, a bulk silicon substrate (not shown in the drawings) is provided, preferably including a single crystal material like silicon, epitaxial silicon, silicon germanium or silicon carbide, a mask layer (not shown in the drawings) is next formed on the bulk silicon substrate, and at least one patterning process is performed through the mask layer, to etch the bulk silicon substrate to form the nanowire structures 110. However, in another embodiment, the nanowire structures 110 may also be formed through firstly forming a mask layer (not shown in the drawings) on the substrate 100, followed by performing an epitaxial growth process, forming an epitaxial layer (not shown in the drawings, including a crystal material different from that of the substrate 100) over the top surface 100a of the substrate 100, to serve as the nanowire structures 110. Then, after forming the nanowire structures 110, the mask layer is completely removed. It is noted that, the at least one patterning process or the epitaxial growth process are selectively carried out along a specific grain boundary, so that, each of the nanowire structures 110 may therefore present in a square or hexagonal cross-sectional shape from a top view (not shown in the drawings), but not limited thereto.

As shown in FIG. 4, a trimming process is performed on the nanowire structures 110, etching each of the nanowire structures 110 to form nanowire structures 112 with a relative smaller width W2. On the other hand, the cross-sectional view of each of the nanowire structures 110 may be changed from the square or the hexagonal shape into a circular shape or nearly in a circular after performing the trimming process, but not limited thereto. People skilled in the art should fully understand that, in one embodiment, the nanowire structures 112 with the smaller width W2, and the circular shape or nearly in circular shape may also be formed directly through the at least one patterning process or the epitaxial growth process. Accordingly, the trimming process may be omitted under the requirement of simplifying the process flow.

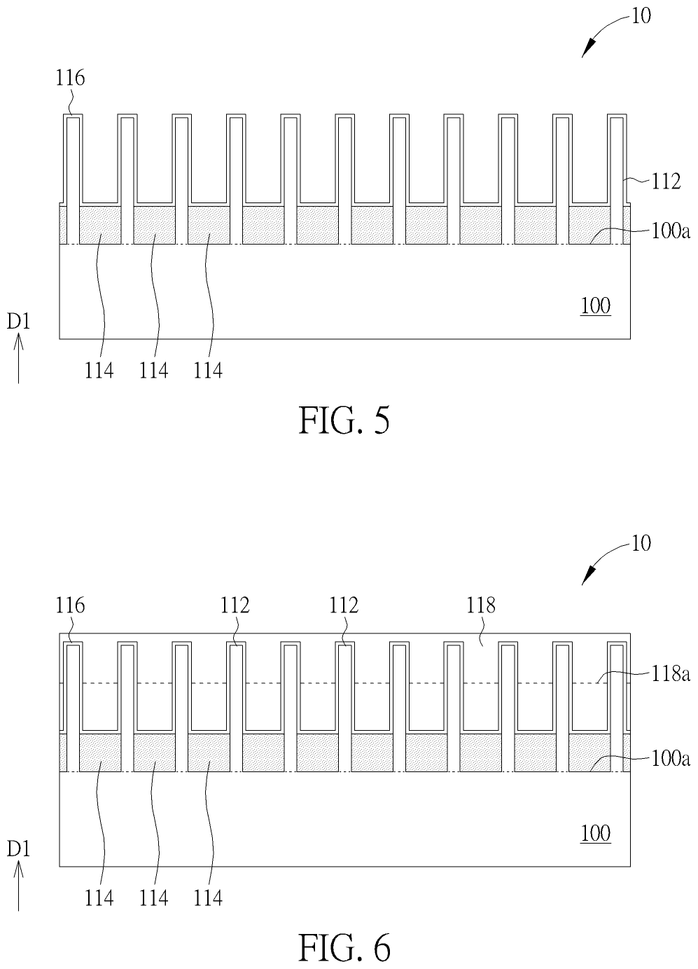

As shown in FIG. 5, a first selectively deposition process preferably being an epitaxial growth process is performed on the substrate 100, to form a doped semiconductor material with a low-resistance or a metal material on the top surface 100a of the substrate 100, to serve as the first source/drain structure 114. In one embodiment, the doped semiconductor material or the metal material for example includes silicon, silicon germanium, titanium, tantalum, aluminum, copper, tungsten or a combination thereof, but not limited thereto. Then, an etching back process is performed based on different etching rates between the first source/drain structure 114 and the nanowire structures 112, so that the first source/drain structure 114 only disposed at a lower half portion of each of the nanowire structures 112, to surround the lower half portion of each of the nanowire structures 112. Next, a dielectric material 116 is formed, conformally covering on the nanowire structures 112 and the first source/drain structure 114. The formation of the dielectric material layer 116 is accomplished by performing a deposition process such as an atomic layer deposition (ALD) process, with the dielectric material layer 116 for example including a single dielectric material or a composition dielectric material like silicon oxide, silicon nitride, silicon oxynitride, or a suitable material with a low-dielectric constant. Alternately, the dielectric material layer 116 may also be formed through a thermal oxidation process, such that, the dielectric material layer 116 formed on the nanowire structures 112 and the first source/drain structure 114 may therefore include different dielectric materials, but not limited thereto.

As shown in FIG. 6, a metal deposition process such as a chemical deposition process or a physical deposition process, is performed on the substrate 100, to form a metal layer 118 on the dielectric material layer 116, with the metal layer 118 filling in the spacer between each of the nanowire structures 112 and covering top surfaces of the nanowire structures 112. In other words, the metal layer 118 surrounds the entire portion of each of the nanowire structures 112. It is noted that, the metal deposition process preferably includes two-staged deposition process, to previously define an etching stop layer 118a within the metal layer 118. People skilled in the art should fully understand that the height of the etching stop layer 118a formed within the metal layer 118 may be adjusted based on the required channel width of the transistor formed in the subsequent process, and which is not limited by what is shown in FIG. 6.

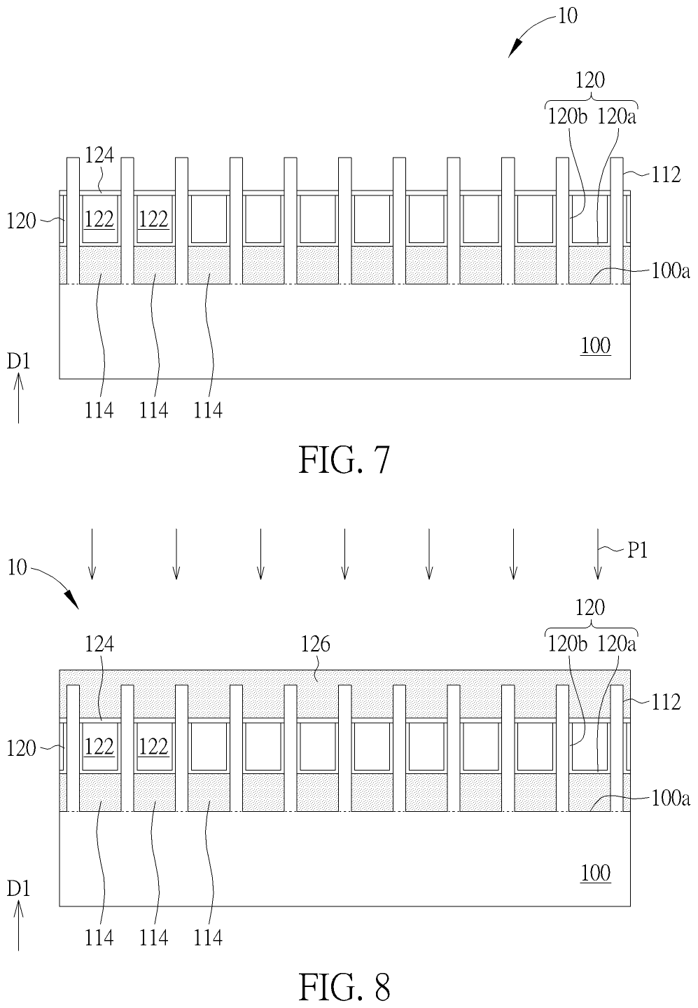

As shown in FIG. 7, at least one etching back process is performed, to remove the metal layer 118 and the dielectric material layer 116 over the etching stop layer 118a, thereby exposing the top surface and the upper-half portion of each of the nanowire structures 112, and simultaneously forming the gate structure 122 and the gate dielectric layer 120. The gate structure 122 wraps a portion of each of the nanowire structures 112, between the gate dielectric layer 120 and the first source/drain structure 114. The gate dielectric layer 120 further includes a first portion 120a horizontally formed between the gate structure 122 and the first source/drain structure 114 underneath, and a second portion 120b vertically formed between the gate structure 122 and each of the nanowire structures 122. Then, a deposition process and an etching back process are next performed, to form a spacer 124 on the gate structure 122. Alternately, in another embodiment, the spacer 124 may also be formed by firstly performing an oxidation process or a nitridation process, followed by performing an etching back process based on the different etching rates between the oxide/nitride formed on surfaces of the nanowire structures 112 and the oxide/nitride formed on surfaces of the gate structure 122, to completely remove the oxide/nitride formed on the surfaces of the nanowire structures 112, and to remain the oxide/nitride formed on the surfaces of the gate structure 122 serving as the spacer 124. In one embodiment, the spacer 124 for example includes a dielectric material like silicon oxide, silicon nitride, silicon oxynitride or a suitable material with a low-dielectric constant, but not limited thereto.

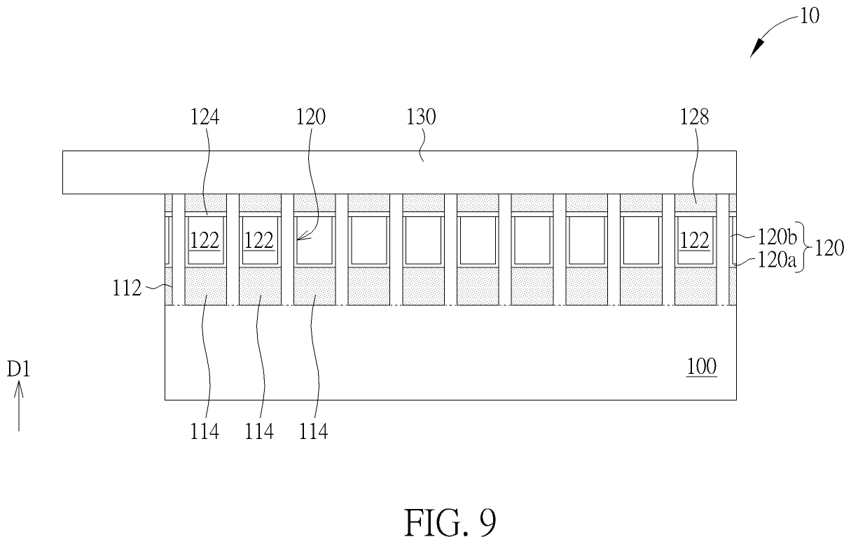

As shown in FIG. 8, a second selectively deposition process such as an epitaxial growth process, is performed to form a conductive material layer 126 on the spacer 124, to cover the top surface and the upper-half portion of each of the nanowire structures 112 again. In one embodiment, the conductive material layer 126 for example includes a doped semiconductor material with a lower-resistance, or a metal material such as silicon, silicon germanium, titanium, tantalum, aluminum, copper, tungsten or a combination thereof, and preferably includes the same conductive material as that of the first source/drain structure 114, but not limited thereto. Then, a first planarization process P1 such as a chemical mechanical polishing process is performed, to remove a portion of the conductive material layer 126 and a portion of each nanowire structure 112 from the top surface of the conductive material layer 126, thereby forming the second source/drain structure 128 as shown in FIG. 9.

As shown in FIG. 9, a second interconnection layer 130 directly in contact with the second source/drain structure 128 and each of the nanowire structures is 112 formed, with the second interconnection layer 130 for example including a low-resistant metal material including but not limited to titanium, tantalum, aluminum, copper, tungsten or a combination thereof, to electrically connect the second source/drain structure 128. Furthermore, in one embodiment, before forming the second interconnection layer 130, a metal silicide layer (not shown in the drawings) may be optionally formed on top surfaces of each of the nanowire structures 112 and the second source/drain structure 128, to reduce sheet resistance and contact resistance.

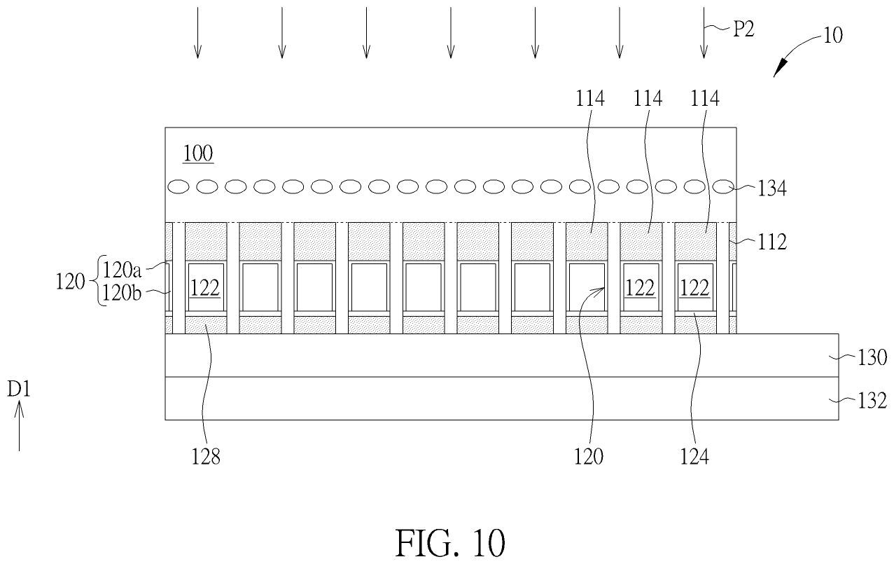

Then, as shown in FIG. 10, a second planarization process P2 is performed, and which may include sequentially performing an ion implantation process and a chemical mechanical polishing process, to completely remove the substrate 100. Firstly, a carrier substrate 132 is formed on the second interconnection layer 130, and the whole structure of the semiconductor device 10 may be reversed through the carrier substrate 132, with a bottom surface of the substrate 100 being faced upwardly. Then, the ion implantation process is formed through the bottom surface, and which includes but not limited to the following steps. Firstly, a plurality of ions (not shown in the drawings) such as hydrogen ions or oxygen ions is uniformly implanted into the substrate 100 with a high dosage. Then, a thermal treatment is performed on the ions, to generate a plurality of bubbles 134 thereby separating a portion of the substrate 100 from a rest portion of the substrate 100, to thin down the substrate 100. After that, the chemical mechanical polishing process is performed to remove the rest portion of the substrate 100.

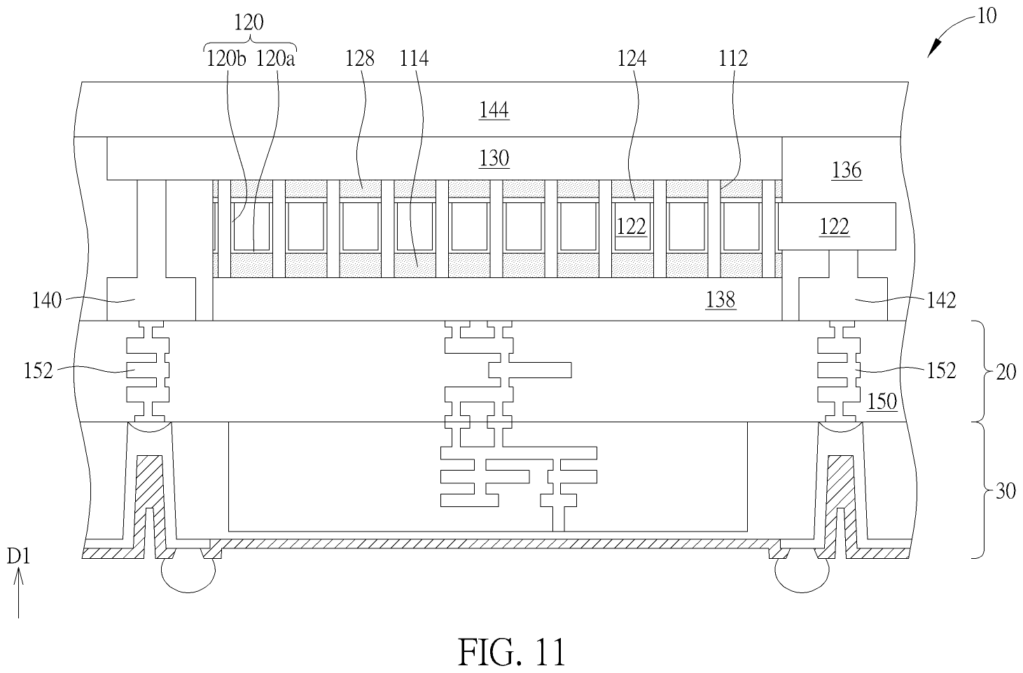

Following these, as shown in FIG. 11, a first interconnection layer 138 is formed to directly in contact with and to electrically connect to the first source/drain structure 114. Also, as forming the first interconnection layer 138, conductive structures 140, 142 are also formed under the second interconnection layer 130 and the gate structure 122, to directly in contact with and to electrically connect to the second interconnection layer 130 and the gate structure 122. Then, the second interconnection layer 130 and the gate structure 122 enable to electrically connect to the same side (namely, the bottom side as s shown in FIG. 11) of the first source/drain structure 114 through the conductive structures 140, 142, respectively. Accordingly, the first source/drain structure 114, the gate structure 122, and the second source/drain structure 128 stacked sequentially and individually surrounding a portion of each of the nanowire structures 122 will together form a transistor having the vertical channel, thereby performing like a gate-all-around function. Also, the first source/drain structure 114, the second source/drain structure 128, and the gate structure 128 may further connect to other functional devices or elements such as a memory device, a logic device, a central processing unit or an analogue device, through the first interconnection layer 138, the second interconnection layer 130 and the conductive structures 140, 142, but not limited thereto.

Through these performances, the fabricating method of the semiconductor device 10 according to the preferably embodiment of the present disclosure is completed. According to the fabricating method of the present embodiment, the transistor having the vertical channel is formed to improve crucial etching process, as well as the channel width without increasing the occupied area of the transistor. In this way, the semiconductor device 10 formed thereby may not only reduce the current leakage, but also gain better performance by improving the functions and reducing the power consumption through adjusting the channel thickness of the semiconductor device 10.

As mentioned above, the semiconductor device 10 of the present disclosure includes a gall-all-around field effect transistor having a vertical channel, and which can be integrated into currently semiconductor processes, for example replacing a common metal oxide semiconductor field effect transistor (MOSFET) or a fin field effect transistor (FinFET) with the semiconductor device 10, to form various functional chips and system chips. Alternately, a chip (not shown in the drawings) may be provided additionally, with the chip including hundreds of millions of the gall-all-around field effect transistors as shown in FIG. 1 and FIG. 2, to be further integrated with other non-functional chips, functional chips like a memory chip, a logic chip or a central processing unit chip, or system on a chip (SoC), to form a three-dimensional integration circuit.

For example, as shown in FIG. 11, a package layer 144 is additionally disposed on the second interconnection layer 130 of the semiconductor device 10, covering and sealing one side (namely, the side where the second source/drain structure 128 is located) of the transistor. Then, the first interconnection layer 138 and the conductive structures 140, 142 are further connected to a plurality of conductive structures 152 disposed on a chip 20. The conductive structures 152 are disposed in a dielectric layer 150, and which may include any suitable plug and/or conductive layer, to serve as an interposer, a functional chip, a system on chip or the like. In one embodiment, the structures include conductive 152 may a low-resistant metal material, such as titanium, tantalum, aluminum, copper or tungsten, but not limited thereto. Following these, the conductive structures 152 of the chip 20 may be further connected to a bonding structure 30 disposed underneath optionally, with the bonding structure 30 for example including a package substrate or a printed circuit board (PCB), but not limited thereto. In this way, the semiconductor device 10 may be applied to a three-dimensional stacked structure, in which the first interconnection layer 138 and the conductive structures 140, 142 are directly connect to other functional devices or elements through simultaneously bonding metal materials to metal materials, and bonding dielectric materials to dielectric materials, by using a Cu—Cu hybrid bonding technology.

Overall speaking, the semiconductor device of the present disclosure includes two source/drain structures and a gate structure stacked in sequence in the vertical direction to respectively wrap a portion of a nanowire structure, to jointly form a gate-all-around field effect transistor having a vertical channel. With these arrangements, the semiconductor device of the present disclosure may effectively increase the channel width without increasing occupied area of the transistor, and improve the reliability and integration of electron transmission, thereby achieving better operation performance. Moreover, the semiconductor device is allowable to be further applied to a three-dimensional stacked structure, by further electrically connecting to other functional devices or components such as a memory device, a logic device, a central processing unit or an analog device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a plurality of nanowire structures, extended in a vertical direction;
a first source/drain structure and a second source/drain structure, stacked in the vertical direction;
a gate structure, disposed between the first source/drain structure and the second source/drain structure in the vertical direction, wherein the first source/drain structure, the second source/drain structure and the gate structure respectively wraps a portion of each of the nanowire structures; and
a gate dielectric layer, disposed between the gate structure and each of the nanowire structures, and between the gate structure and the first source/drain structure.

2. The semiconductor device according to claim 1, further comprising a spacer disposed between the second source/drain structure and the gate structure.

3. The semiconductor device according to claim 1, wherein the gate dielectric layer further comprises a first portion between the first source/drain structure and the gate structure, and a second portion disposed on each of the nanowire structure, and the first portion and the second portion have different materials.

4. The semiconductor device according to claim 1, further comprising:
a first interconnection layer, surrounded by an insulating layer; and
a second interconnection layer, surrounded by the insulating layer, wherein the first interconnection layer and the second interconnection layer are stacked in the vertical direction, and are electrically connected to the first source/drain structure and the second source/drain structure, respectively.

5. The semiconductor device according to claim 4, further comprising:
a package layer, covering on the second interconnection layer; and
a first conductive structure, electrically connected the second interconnection layer, wherein a bottom surface of the first conductive structure and a bottom surface of the first interconnection layer are coplanar.

6. The semiconductor device according to claim 5, further comprises:
a chip, comprising a plurality of second conductive structures electrically connected to the first conductive structure and the first interconnection layer, respectively; and
a bonding structure, disposed under the chip to electrically connected the chip.

7. The semiconductor device according to claim 6, wherein the bounding structure comprising a package substrate or a printed circuit board.

8. A fabricating method of a semiconductor device, comprising:
forming a plurality of nanowire structures extending in a vertical direction;
forming a first source/drain structure and a second source/drain structure stacked sequentially in the vertical direction;
forming a gate structure between the first source/drain structure and the second source/drain structure in the vertical direction, wherein the first source/drain structure, the gate structure, and the second source/drain structure respectively wraps a portion of each of the nanowire structures; and
forming a gate dielectric layer, between the gate structure and each of the nanowire structures, and between the gate structure and the first source/drain structure.

9. The method of fabricating the semiconductor device according to claim 8, further comprising:
providing a bulk substrate;
performing a patterning process on the bulk substrate to form the nanowire structures over a substrate; and
performing a first selective deposition process on the substrate, to form the first source/drain structure.

10. The method of fabricating the semiconductor device according to claim 9, wherein the gate dielectric layer is formed after forming the first source/drain structure, through a thermal oxidation process or a deposition process.

11. The method of fabricating the semiconductor device according to claim 9, further comprising:
before forming a first source/drain structure, trimming the nanowire structures.

12. The method of fabricating the semiconductor device according to claim 9, after forming the gate dielectric layer, further comprising:
performing a metal deposition process on the substrate to form the gate structure; and
performing a second selective deposition process on the substrate, to form the second source/drain structure.

13. The method of fabricating the semiconductor device according to claim 12, forming the gate structure further comprising:
forming a metal layer on the first source/drain structure, covering top surfaces of the nanowire structures; and
partially removing the metal layer, to expose the top surfaces of the nanowire structures.

14. The method of fabricating the semiconductor device according to claim 12, further comprising:
before forming the second source/drain structure, forming a spacer on the gate structure.

15. The method of fabricating the semiconductor device according to claim 9, further comprising:
forming a first interconnection layer on the first source/drain structure; and
forming a second interconnection layer on the second source/drain structure, wherein the first interconnection layer and the second interconnection layer are stacked in the vertical direction, and are electrically connected to the first source/drain structure and the second source/drain structure, respectively.

16. The method of fabricating the semiconductor device according to claim 15, before forming the second interconnection layer, further comprising:
removing the substrate.

17. The method of fabricating the semiconductor device according to claim 16, removing the substrate further comprising:
implanting a plurality of ions into the substrate;
performing a thermal treatment on the ions; and
removing a portion of the substrate through the ions.

18. The method of fabricating the semiconductor device according to claim 15, further comprising:
forming a package layer on the second interconnection layer; and
while forming the first interconnection layer, forming a first conductive structure under the second interconnection layer, wherein the first conductive structure is electrically connected to the second interconnection layer, and is coplanar with a bottom surface of the first interconnection layer.

19. The method of fabricating the semiconductor device according to claim 18, further comprises:
forming a chip, the chip comprising a plurality of second conductive structures respectively connected to the first conductive structure and the first interconnection layer; and
forming a bonding structure on the chip.

20. The method of fabricating the semiconductor device according to claim 19, wherein the bounding structure comprises a package substrate and a printed circuit board.
